(19) United States
(12) Patent Application Publication
(10) Pub. No.: US 2013/0341807 A1
(43) Pub. Date: Dec. 26, 2013

(54) SEMICONDUCTOR PACKAGE STRUCTURE

(71) Applicant: Po-Chun Lin, Changhua County (TW)

(72) Inventor: Po-Chun Lin, Changhua County (TW)

(21) Appl. No.: 13/531,601

(22) Filed: Jun. 25, 2012

(51) Int. Cl. H01L 23/28

(52) U.S. Cl. 257/787; 257/E23.116

(57) ABSTRACT

A semiconductor package structure includes a package substrate having a first surface, a second surface opposite to the first surface, and a sidewall surface between the first surface and the second surface. A semiconductor device is mounted on the first surface. A mold cap encapsulates the semiconductor device. The mold cap includes a vertical extension portion covering the sidewall surface and a horizontal extension portion covering a periphery of a solder ball implanting region on the second surface.

### BACKGROUND OF THE INVENTION

1. Field of the Invention

The present invention relates to a package structure, particularly to a semiconductor package structure capable of reducing warpage and preventing delamination.

2. Description of the Prior Art

As known in the art, semiconductor integrated circuits are fabricated on a semiconductor wafer by using a number of process steps, for example, film deposition, ion implantation, etching and lithographic processes. After wafer fabrication, the wafer is subjected to die singulation process that is typically performed by using a saw blade. The individual die is then packaged together with a package substrate or chip carrier. Typically, during a packaging process, the chip or die is encapsulated by molded polymer resin that also partially encapsulating a top surface of the package substrate on which the die is mounted.

One problem with the molded plastic package is that subsequent to molding, internal delamination frequently occurs. In severe cases, a crack develops, creating an ingress site for contaminants resulting in reliability issue of the chip package. The location that is particularly prone to delamination is the interface of the package substrate and the molding resin. Delamination at the interface of the package substrate and the molding resin is primarily due to inadequate adhesion between the substrate and the molding resin and/or stresses generated by coefficient of thermal expansion mismatch and singularizing process. Another problem with the molded plastic package is the package warpage induced by thermal stress and package structure unbalance.

### SUMMARY OF THE INVENTION

It is one object of the invention to provide an improved semiconductor package structure to overcome the above-mentioned prior art problems and shortcomings.

According to one aspect of the present invention, a semiconductor package structure includes a package substrate having a first surface, a second surface opposite to the first surface, and a sidewall surface between the first surface and the second surface; a semiconductor device mounted on the first surface; a plurality of bond wires electrically coupling the semiconductor device to the package substrate; and a mold cap encapsulating at least the semiconductor device and the bond wires, wherein the mold cap comprises a vertical extension portion covering the entire sidewall surface and a horizontal extension portion covering a periphery of a solder ball implanting region on the second surface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram showing a semiconductor package structure capable of reducing warpage and preventing delamination in accordance with one embodiment of this invention.

FIG. 2 is a schematic, cross-sectional diagram showing a semiconductor package structure capable of reducing warpage and preventing delamination in accordance with another embodiment of this invention.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

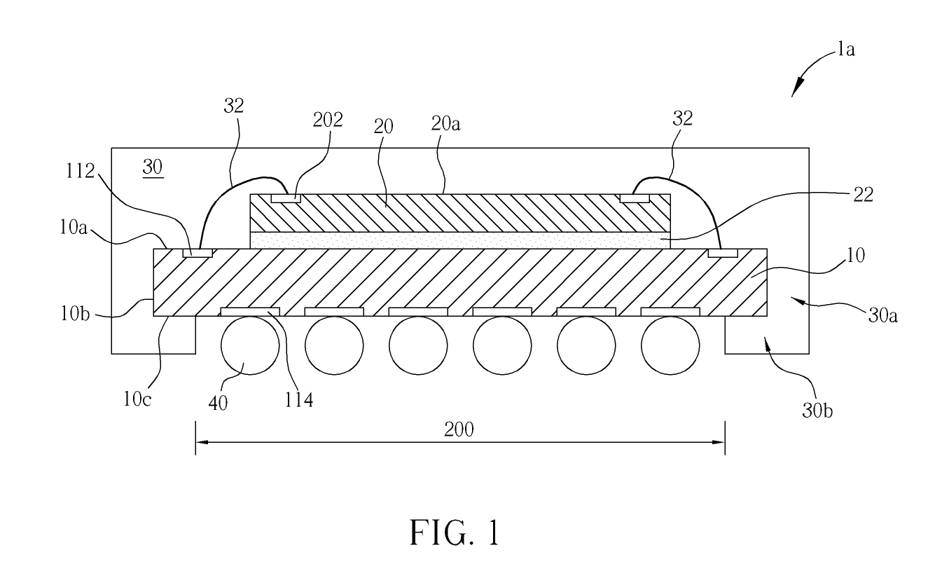

FIG. 1 is a schematic, cross-sectional diagram showing a semiconductor package structure capable of reducing warpage and preventing delamination in accordance with one embodiment of this invention. As shown in FIG. 1, the semiconductor package structure la comprises a package substrate 10 having a first surface 10a, a second surface 10c that is opposite to the first surface 10a, and a sidewall surface 10b between the first surface 10a and the second surface 10c. The sidewall surface 10b is substantially perpendicular to both of the first surface 10a and the second surface 10c. The package substrate 10 may be a plastic substrate having an insulating core layer such as glass-fiber materials or the like, and multiple layers of conductive traces and multiple layers of dielectric materials laminated on the insulating core layer. The multiple layers of conductive traces may be interconnected to each other by using a plurality of via plugs or so-called plated through holes (PTHs). Optionally, a solder mask (not explicitly shown) may be used to cover either the first surface 10a or the second surface 10c to protect the topmost layer of the conductive traces. It is to be understood that the package substrate may be ant other type of substrate such as molding compound or epoxy based substrate wherein the solder mask may be omitted.

A semiconductor device 20 such as a semiconductor integrated circuit chip is mounted on the first surface 10a within a predetermined chip-mounting region. The semiconductor device 20 may be adhered to the first surface 10a by using an adhesive layer 22. The semiconductor device 20 has an active surface 20a having thereon a plurality of bonding pads 202. The bonding pads 202 are electrically connected to respective bond fingers 112 disposed on the first surface 10a of the package substrate 10 with a plurality of bond wires 32. In an alternative case, the semiconductor device 20 may be flipped and with it active surface face-down mounted on the first surface 10a via bumps or the like. On the second surface 10c of the package substrate 10, a solder ball implanting region 200 is defined. A plurality of solder pads 114 are provided on the second surface 10c within the solder ball implanting region 200. A plurality of solder balls 40 are formed on respective solder pads 114.

A mold cap 30 is provided to encapsulate the semiconductor device 20, the bond wires 32, and at least a portion of the top surface 10a of the package substrate 10. The mold cap 30 further extends to the second surface 10c to cover a periphery of the solder ball implanting region 200. In another embodiment, the aforesaid adhesive layer 22 may be replaced with the mold cap 30. As shown in FIG. 1, the mold cap 30 comprises a vertical extension portion 30a that covers the entire sidewall surface 10b and a horizontal extension portion 30b that may act as a mold lock to resist package warpage. The vertical extension portion 30a connects the main portion of the mold cap 30 to the underlying horizontal extension portion 30b. Since the entire sidewall surface 10b is covered with the horizontal extension portion 30b, delamination can be prevented.

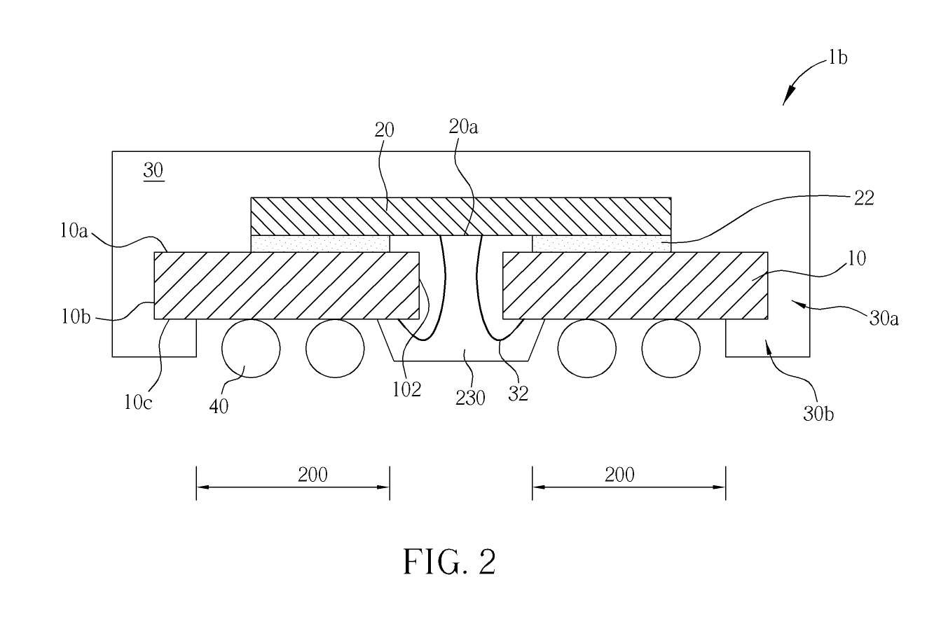

FIG. 2 is a schematic, cross-sectional diagram showing a semiconductor package structure capable of reducing warpage and preventing delamination in accordance with another embodiment of this invention, wherein like numeral numbers designate like regions, layers or elements. As shown in FIG. 2, the semiconductor package structure lb comprises a package substrate 10 having a central slot or window 102. A semiconductor device 20 such as a DDR DRAM chip is provided face-down mounted on the first surface 10a of the package substrate 10. The active surface 20a of the semiconductor device 20 is electrically coupled to the second surface 10c through the bond wires 32 that pass through the window 102. Likewise, a mold cap 30 is provided to encapsulate the semiconductor device 20, the bond wires 32, the window 102, and at least a portion of the top surface 10a of the package substrate 10. The mold cap 30 further extends to the second surface 10c to cover a periphery of the solder ball implanting region 200. The mold cap 30 comprises a vertical extension portion 30a that covers the entire sidewall surface 10b and a horizontal extension portion 30b that may act as a mold lock to resist package warpage. The vertical extension portion 30a connects the main portion of the mold cap 30 to the underlying horizontal extension portion 30b. Since the entire sidewall surface 10b is covered with the horizontal extension portion 30b, delamination can be prevented.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package structure, comprising:
a package substrate having a first surface, a second surface opposite to the first surface, and a sidewall surface between the first surface and the second surface;
a semiconductor device mounted on the first surface; and
a mold cap encapsulating at least the semiconductor device, wherein the mold cap comprises a vertical extension portion covering the sidewall surface and a horizontal extension portion covering a periphery of a solder ball implanting region on the second surface.

2. The semiconductor package structure according to claim 1 wherein the vertical extension portion connects a main portion of the mold cap to the horizontal extension portion.

3. The semiconductor package structure according to claim 1 wherein the package substrate comprises a slot.

4. The semiconductor package structure according to claim 3 further comprising a plurality of bond wires electrically coupling the semiconductor device to the package substrate.

5. The semiconductor package structure according to claim 4 wherein the bond wires pass through the slot.

6. The semiconductor package structure according to claim 1 further comprising an adhesive layer to adhere the semiconductor device to the first surface of the package substrate.

7. The semiconductor package structure according to claim 1 further comprising a solder mask covering either the first surface or the second surface.
